(19) United States
(12) Patent Application Publication
(10) Pub. No.: US 2020/0194526 A1
(43) Pub. Date: Jun. 18, 2020

(54) THIN FILM TRANSISTOR SUBSTRATES AND DISPLAY PANELS

(71) Applicant: YUNGU (GU'AN) TECHNOLOGY CO., LTD., Langfang (CN)

(72) Inventor: Haofeng ZHANG, Kunshan (CN)

(21) Appl. No.: 16/801,149

(22) Filed: Feb. 26, 2020

Related U.S. Application Data
(63) Continuation of application No. PCT/CN2019/085064, filed on Apr. 29, 2019.

(30) Foreign Application Priority Data
Aug. 20, 2018 (CN) 201810948118.5

(51) Int. Cl. H01L 27/32; H01L 51/00

(52) U.S. Cl. CPC H01L 27/3258; H01L 51/0097; H01L 27/1218; H01L 27/3262; H01L 27/3246

(57) ABSTRACT

A TFT substrate and a display panel. The TFT substrate includes a substrate, a functional layer, and an insulating layer. The functional layer includes an active layer and a gate electrode sequentially disposed on the substrate. The insulating layer includes a gate insulating layer and an interlayer insulating layer. The gate insulating layer is disposed on the substrate and covering the active layer. The interlayer insulating layer is disposed on the gate insulating layer and covering the gate electrode. The interlayer insulating layer defines a first hollowed-out region at a position corresponding to two ends of the active layer. And the first hollowed-out region is filled with a flexible organic material.

### CROSS-REFERENCES TO RELATED APPLICATIONS

This application is a continuation application of international patent application PCT/CN2019/085064, filed on Apr. 29, 2019, which claims the priority benefit of Chinese patent application No. 201810948118.5, entitled “TFT SUBSTRATE AND DISPLAY PANEL”, and filed on Aug. 20, 2018. The entireties of these applications are incorporated by reference herein for all purposes.

### TECHNICAL FIELD

The present application relates to the display technology.

### BACKGROUND

Active matrix organic light emitting diode (AMOLED) display panels have characteristics such as self-illumination, low power consumption, fast response speed, high contrast, and relatively wide viewing angle. Therefore, the AMOLED display panels have a broad application prospect in the field of display technology.

### SUMMARY

The present application provides a TFT substrate. The TFT substrate includes a substrate, a functional layer, and an insulating layer. The functional layer includes an active layer and a gate electrode sequentially disposed on the substrate. The insulating layer includes a gate insulating layer and an interlayer insulating layer. The gate insulating layer is disposed on the substrate and covering the active layer. The interlayer insulating layer is disposed on the gate insulating layer and covers the gate electrode. The interlayer insulating layer defines a first hollowed-out region at a position corresponding to two ends of the active layer. The first hollowed-out region is filled with a flexible organic material.

In an embodiment, a width of the interlayer insulating layer between two first hollowed-out regions is greater than or equal to a width of the active layer.

In an embodiment, the flexible organic material includes a first flexible organic layer and a second flexible organic layer located above the first flexible organic layer. And a material of the second flexible organic layer is different from a material of the first flexible organic layer.

In an embodiment, the first flexible organic layer is a non-Newtonian fluid.

In an embodiment, the second flexible organic layer is a planarization layer.

In an embodiment, the gate insulating layer defines a second hollowed-out region at a position corresponding to the two ends of the active layer. And the flexible organic material is filled in the second hollowed-out region.

In an embodiment, the functional layer further includes a source electrode and a drain electrode. And the insulating layer further includes a protecting layer covering the source electrode and the drain electrode.

In an embodiment, the protecting layer further covers the interlayer insulating layer located between the source electrode and the drain electrode.

In an embodiment, the TFT substrate further includes a buffer layer covering the substrate. The flexible organic material is in contact with the buffer layer. The insulating layer further includes a barrier layer disposed between the buffer layer and the active layer. The barrier layer defines a third hollowed-out region at a position corresponding to the two ends of the active layer. And the flexible organic material is in contact with the buffer layer and further filled in the third hollowed-out region.

In an embodiment, a width of the barrier layer is greater than or equal to a width of the active layer.

In an embodiment, the first hollowed-out region, the second hollowed-out region, and the third hollowed-out region are in communication with each other, so that the first hollowed-out region, the second hollowed-out region, and the third hollowed-out region are continuously filled with the flexible organic material.

In an embodiment, the flexible organic material includes at least one of polyacrylate and polyimide.

In an embodiment, a material of the insulating layer includes at least one of silicon oxide and silicon nitride.

In an embodiment, the TFT substrate includes a plurality of alternately stacked functional layers and insulating layers. The plurality of alternately stacked functional layers and insulating layers each has a patterned structure. And an overlapping area exists between a projection of the patterned structure of each of the functional layers on the substrate and a projection of the patterned structure of each of the insulating layers on the substrate.

The present application further provides a display panel including the aforementioned TFT substrate.

In an embodiment, the display panel further includes a light-emitting structure disposed on the TFT substrate. The light-emitting structure includes a first electrode, an organic light-emitting layer, and a second electrode stacked with each other. The organic light-emitting layer includes pixels and a pixel defining layer disposed between adjacent pixels. The pixel defining layer defines a channel structure between two adjacent pixels.

In an embodiment, the light-emitting structure is an OLED structure.

The details of one or more embodiments of this application are set forth in the accompanying drawings and description below. Other features, objects and advantages of the present application will become apparent from the description, the accompanying drawings, and the claims.

### BRIEF DESCRIPTION OF THE DRAWINGS

To better describe and illustrate embodiments and/or examples of the present application, references can be made to one or more drawings. The additional details or examples used to describe the drawings should not be construed as limiting the scope of any of the disclosed application, the presently described embodiments and examples, and the presently understood best modes of the application.

FIG. 1 shows a schematic cross-sectional view of a TFT substrate in an embodiment.

FIG. 2 shows a schematic cross-sectional view of a TFT substrate in another embodiment.

FIG. 3 shows a schematic cross-sectional view of a TFT substrate in yet another embodiment.

FIG. 4 shows a schematic cross-sectional view of a TFT substrate in yet another embodiment.

FIG. 5 shows a schematic cross-sectional view of a TFT substrate in yet another embodiment.

FIG. 6 shows a schematic cross-sectional view of a TFT substrate in yet another embodiment.

FIG. 7 shows a schematic cross-sectional view of a TFT substrate in yet another embodiment.

FIG. 8 shows a schematic cross-sectional view of a display panel in an embodiment.

FIG. 9 shows a schematic cross-sectional view of a display panel in another embodiment.

### DETAILED DESCRIPTION OF THE INVENTION

An AMOLED display panel usually needs to undergo a series of display panel reliability tests after being manufactured. An impact resistance of the screen is usually examined in a drop ball test. In this test scheme and in a practical use, a stress surge phenomenon may occur at a local region of the display screen due to a transient impact, which may cause display anomalies. Especially for a flexible screen that is subjected to the transient impact, due to the absence of a rigid protecting layer, the stress increases sharply, and the display region is more likely to have a display defect such as a dark spot, a bright spot, and a colored spot.

An additional buffer material is usually used to ameliorate these display anomalies, but this will increase the thickness of the display panel and degrade the bending performance of the display panel.

In order to make the above objects, features and advantages of the present application more apparent and better understood, embodiments of the application will be fully described hereinafter with reference to the drawings. Numerous specific details are set forth in the following description in order to provide a thorough understanding of the present application. However, the present application can be implemented in many other ways different from those described herein, and a person skilled in the art can make similar modifications without departing from the application, and therefore, the present application is not limited by the specific embodiments disclosed below.

It should be understood that when an element is described as “formed on” another element, it is either directly formed on the other element or indirectly formed on the other element through an intermediate element. The terms “up”, “down”, and the like used herein are for illustrative purposes only and are not intended to be the only embodiment.

All technical and scientific terms used herein have the same meaning as commonly understood by one of ordinary skill in the art to which this application applies, unless otherwise defined. The terms used in the specification of this application herein are for the purpose of describing specific embodiments only and are not intended to limit this application. The term “and/or” used herein includes any and all combinations of one or more of the associated and listed items.

At present, an AMOLED display panel usually needs to undergo a series of display panel reliability tests after being manufactured. An impact resistance of the screen is usually examined in a drop ball test. In this test scheme and in a practical use, a stress surge phenomenon may occur at a local region of the display panel due to a transient impact, which may cause display anomalies. Especially for a flexible screen that is subjected to the transient impact, due to the absence of a rigid protecting layer, the stress increases sharply, and the display region is more likely to have a display defect such as a dark spot, a bright spot, and a colored spot. Although these display anomalies can be ameliorated by adding an additional buffer material, the thickness of the display panel will be increased and the bending capability of the display panel will be decreased in this way.

Based on this, the present application provides a TFT substrate. The TFT substrate includes a substrate, a functional layer disposed on the substrate, and an insulating layer correspondingly covering the functional layer. The functional layer has a patterned structure, and the insulating layer has a patterned structure matching the structure of the functional layer. Hollowed-out regions in the patterned structure of the insulating layer are filled with a flexible organic material.

In the present application, the insulating layer of the TFT substrate has a patterned structure that matches the structure of the functional layer, and the hollowed-out regions in the patterned structure of the insulating layer are filled with a flexible organic material. Since the flexible organic material has better buffering property than the material of the insulating layer, stress can be released to the flexible organic material in the hollowed-out regions when the TFT substrate is subjected to an external transient impact. Therefore, the TFT substrate has more buffer space, and the stress can be effectively absorbed and released, so that the purposes of improving the impact resistance and ameliorating the display failures are achieved. In addition, since the flexible organic material has better ductility and bending endurance than an inorganic layer, the flexible TFT substrate can have better bending endurance by using the flexible organic material.

Based on the above solutions, specific embodiments are described in detail below with reference to the drawings.

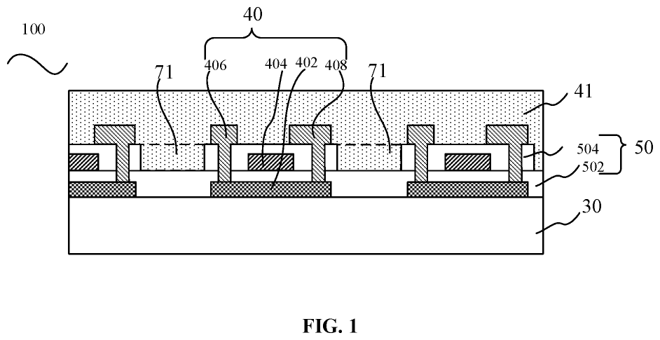

As shown in FIG. 1, an embodiment of the present application provides a TFT substrate 100. In a cross-sectional structure of the TFT substrate 100, the TFT substrate 100 includes a thin film transistor (TFT), a capacitor (not shown in the drawing), and a corresponding conducting circuit (not shown in the drawing). The TFT is an important component in the TFT substrate and controls a luminous intensity of a light-emitting structure.

As shown in FIG. 1, the TFT substrate includes a substrate 30, a functional layer 40 and an insulating layer 50. The substrate 30 can be a flexible substrate or a rigid substrate. The functional layer 40 includes an active layer 402, a gate electrode 404, a source electrode 406, and a drain electrode 408 disposed on the substrate 30 in this order. The insulating layer 50 includes a gate insulating layer 502 disposed on the substrate and covering the active layer 402, and an interlayer insulating layer 504 disposed on the gate insulating layer 502 and covering the gate electrode 404. First hollowed-out regions 71 each is defined in the interlayer insulating layer 504 corresponding to two ends of the active layer 402. The first hollowed-out regions 71 are filled with a flexible organic material 41.

The active layer 402 includes a channel region (not shown), and a source region (not shown) and a drain region (not shown) doped with a dopant. The active layer 402 is disposed on the substrate 30. The gate insulating layer 502 covers the active layer 402 and the substrate 30. The gate electrode 404 is disposed on the gate insulating layer 502. The interlayer insulating layer 504 covers the gate electrode 404 and is in contact with the gate insulating layer 502. A part of the gate insulating layer 502 and a part of the interlayer insulating layer 504 are removed, and contact holes are formed after the removal to expose predetermined areas of the active layer 402. The source electrode 406 and the drain electrode 408 are in contact with the active layer 402 via the contact holes. Then, the insulating layer of the TFT substrate is patterned for covering a necessary pattern of a lower layer. (A main function of the insulating layer in the TFT is to isolate the wiring. But in an actual production, if there is no need to make a contact, the entire insulating layer is continuous. Here, only the part of the insulating layer that is necessary and is required for the isolation is remained, and the part of the insulating layer that does not play an isolating or insulating function is removed. Therefore, the patterning is to cover the necessary pattern of the lower layer.) Such that, the insulating layer 50 becomes a discontinuous film or layer, thereby defining the hollowed-out regions in the insulating layer 50.

In the TFT substrate, the performance of an inorganic material is generally better than that of an organic material. Therefore, the insulating layer 50 in the TFT substrate usually adopts a whole inorganic material layer to achieve functions such as insulation, passivation or blocking. However, the inorganic material has a defect that its hardness is large, so that the stress in the inorganic material is difficult to be absorbed or released. This is not conducive for the TFT substrate to release and absorb the stress when the TFT substrate is subjected to a transient impact. Therefore, in the present application, the hollowed-out regions are filled with the flexible organic material, so that the surged stress is released in these regions during the impact, thereby solving the display failure problem due to the impact.

Specifically, as shown in FIG. 1, the interlayer insulating layer 504 is disposed on the gate insulating layer 502. The interlayer insulating layer 504 is patterned to cover the gate electrode 404. The aforementioned hollowed-out regions include first hollowed-out regions 71 formed in the interlayer insulating layer 504 on two sides of the active layer 402, so that the interlayer insulating layer 504 between adjacent TFTs is discontinuous. The flexible organic material 41 is disposed on the interlayer insulating layer 504 and is filled in the first hollowed-out regions 71. The interlayer insulating layer 504 between two first hollowed-out regions 71 can be patterned to have a width slightly larger than or equal to a width of the active layer 402. The interlayer insulating layer 504 is generally formed of an inorganic insulating material such as silicon oxide and silicon nitride. Since the flexible organic material 41 has a better buffering property than that of the interlayer insulating layer 504, stress can be released to the flexible organic material in the first hollowed-out regions 71 when the TFT substrate is subjected to an external transient impact. Therefore, the TFT substrate has more buffer space to effectively absorb and release the stress, so that the purposes of improving the impact resistance and ameliorating the display failures can be achieved. In addition, since the flexible organic material has better ductility and bending endurance than that of an inorganic layer, the flexible TFT substrate can have better bending endurance by using the flexible organic material.

In addition, in FIG. 1, the flexible organic material 41 can be a planarization layer.

Using the flexible organic material 41 as the planarization layer will not add additional processing steps for manufacturing the TFT substrate. In addition, the planarization layer generally includes a suitable flexible organic material such as polyacrylate or polyimide, which can improve the impact resistance and bending endurance of the TFT substrate and achieve the purpose of ameliorating the display failures.

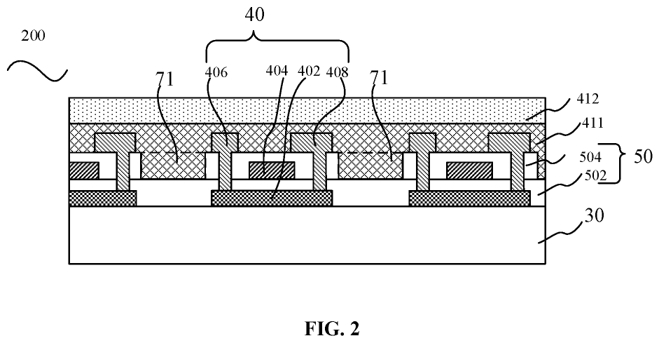

As shown in FIG. 2, in another embodiment, a schematic view of a TFT substrate 200 is shown. The TFT substrate 200 is similar to the TFT substrate 100 shown in FIG. 1 except that the flexible organic material 41 of the TFT substrate 200 includes a first flexible organic layer 411 and a second flexible organic layer 412 located above the first flexible organic layer 411. The material of the second flexible organic layer 412 is different from that of the first flexible organic layer 411. In this embodiment, the second flexible organic layer 412 can be a planarization layer. It provides more choices for the materials and shapes of the flexible organic materials. In an embodiment, the first flexible organic layer 411 can be a non-Newtonian fluid. The non-Newtonian fluid has a good cushioning property and can significantly improve the impact resistance of the TFT substrate. By properly selecting and designing the shape, structure and material of the flexible organic material, better effect can be achieved, the impact resistance of the TFT substrate can be improved, and the purpose of ameliorating the display failures can be achieved.

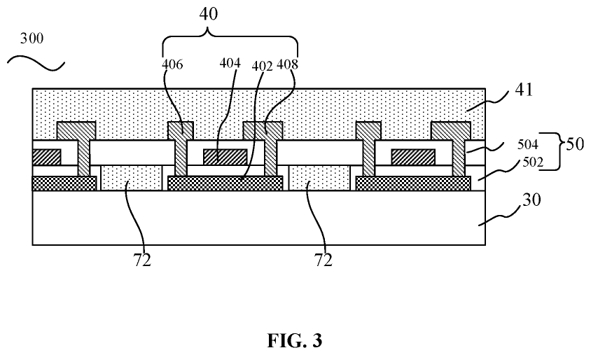

FIG. 3 to FIG. 7 only shows the case that the flexible organic material 41 is a planarization layer, but the embodiments of the present application are not limited thereto. The flexible organic material 41 can include a first flexible organic layer 411 and a second flexible organic layer 412 (not shown in FIG. 3 to FIG. 7) located above the first flexible organic layer 411.

3, in another embodiment, a schematic view of a TFT substrate 300 is shown. In FIG. 3, the gate insulating layer 502 of the insulating layer 50 of the TFT substrate is patterned to cover the active layer 402. Second hollowed-out regions 72 each is defined in the gate insulating layer 502 corresponding to two ends of the active layer 402. The flexible organic material 41 is filled in the second hollowed-out regions 72.

In this embodiment, the gate insulating layer 502 is patterned for covering a necessary pattern of a lower layer, having a pattern necessary for the insulation, and is then filled with the flexible organic material. The gate insulating layer 502 is formed of an inorganic insulating material such as silicon oxide or silicon nitride. Since the flexible organic material has a better buffering property than the inorganic insulating material of the gate insulating layer 502, stress can be released to the flexible organic material in the second hollowed-out regions 72 when the TFT substrate is subjected to an external transient impact. As a result, the TFT substrate has more buffer space, and the stress can be effectively absorbed and released, so that the purposes of improving the impact resistance and ameliorating the display failures are achieved. In addition, since the flexible organic material has better ductility and bending endurance than that of an inorganic layer, the flexible TFT substrate can have better bending endurance by using the flexible organic material.

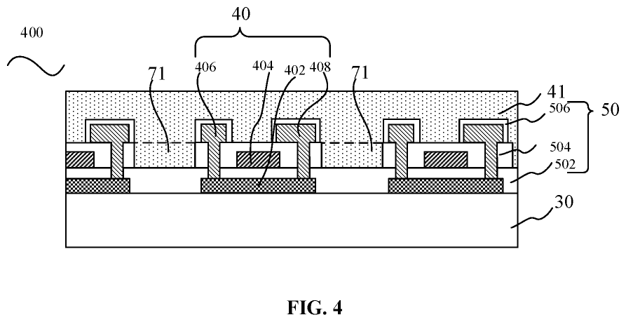

As shown in FIG. 4, in an embodiment, a schematic view of a TFT substrate 400 is shown. The TFT substrate 400 is different from the TFT substrate 100 shown in FIG. 1 in that the insulating layer 50 of the TFT substrate can further include a protecting layer 506 covering the source electrode 406 and the drain electrode 408, and the protecting layer 506 is patterned to cover only the source electrode 406 and the drain electrode 408.

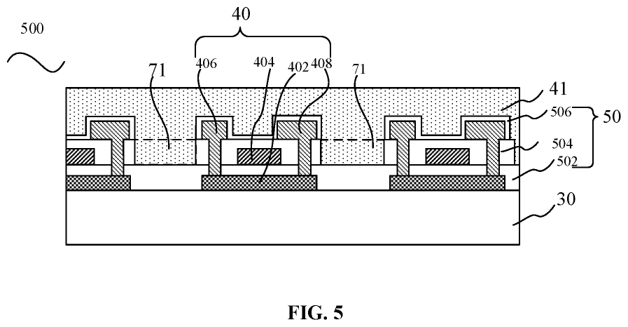

As shown in FIG. 5, in another embodiment, a schematic view of a TFT substrate 500 is shown. The TFT substrate 500 is different from the TFT substrate 400 shown in FIG. 4 in that the protecting layer 506 further covers the interlayer insulation layer 504 located between the source electrode 406 and the drain electrode 408.

In the embodiments of FIG. 4 and FIG. 5, the interlayer insulating layer 504 and the protecting layer 506 are both patterned for covering a necessary pattern of a lower layer, having a pattern necessary for insulation and protection, so that the insulating layer 50 of the TFT substrate is discontinuous, and are then covered and filled with the flexible organic material. Generally, the protecting layer 506 is formed of silicon oxide, silicon nitride, and/or other suitable inorganic insulating materials. The flexible organic material has a better buffering property than the interlayer insulating layer 504 and the protecting layer 506. Therefore, when being subjected to an external transient impact, the TFT substrate has more buffer space for the stress, and the stress can be effectively absorbed and released, so that the purposes of improving the impact resistance and ameliorating the display failures are achieved. In addition, since the flexible organic material has better ductility and bending endurance than that of an inorganic layer, the flexible TFT substrate can have better bending endurance by using the flexible organic material.

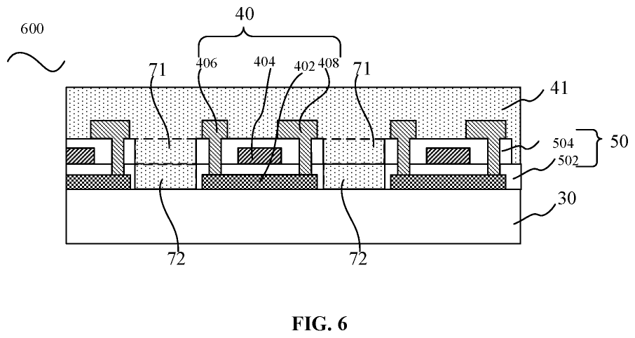

As shown in FIG. 6, in one embodiment, a schematic view of a TFT substrate 600 is shown. The TFT substrate 600 is different from the TFT substrate 100 shown in FIG. 1 in that the gate insulating layer 502 of the TFT substrate is patterned to only cover the active layer 402, and the aforementioned hollowed-out regions include second hollowed-out regions 72. The second hollowed-out regions 72 are formed in the gate insulating layer 502 corresponding to two sides of the active layer 402. The flexible organic material 41 covers the exposed surface of the TFT substrate and is filled in the first hollowed-out regions 71 and the second hollowed-out regions 72. In other embodiments, if the insulating layer 50 of the TFT substrate further includes a protecting layer 506, in addition to patterning the gate insulating layer 502 and the interlayer insulating layer 504, the protecting layer 506 can further be patterned as shown in FIG. 4 or FIG. 5.

In this embodiment, the gate insulating layer 502 and the interlayer insulating layer 504 are both patterned for covering a necessary pattern of a lower layer, having a pattern necessary for insulation, and are then filled with the flexible organic material. The gate insulating layer 502 and the interlayer insulating layer 504 are each formed of the inorganic insulating material such as silicon oxide or silicon nitride. Since the flexible organic material has a better buffering property than the inorganic insulating materials of the gate insulating layer 502 and the interlayer insulating layer, stress can be released to the flexible organic material in the first hollowed-out regions 71 and the second hollowed-out regions 72 when the TFT substrate is subjected to an external transient impact. As a result, the TFT substrate has more buffer space, and the stress can be effectively absorbed and released, so that the purposes of improving the impact resistance and ameliorating the display failures are achieved. In addition, since the flexible organic material has better ductility and bending endurance than that of an inorganic layer, the flexible TFT substrate can have better bending endurance by using the flexible organic material.

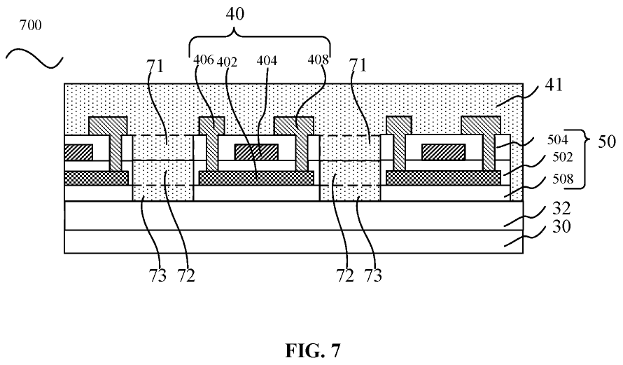

In an embodiment, as shown in FIG. 7, a schematic view of a TFT substrate 700 is shown. The TFT substrate 700 is different from the TFT substrate 600 shown in FIG. 6 in that the TFT substrate 700 further includes a buffer layer 32 covering the substrate 30, and the insulating layer 50 of the TFT substrate 700 further includes a barrier layer 508 disposed between the buffer layer 32 and the active layer 402. The barrier layer 508 is patterned, and third hollowed-out regions 73 each is defined in the barrier layer 508 corresponding to two ends of the active layer 402. The flexible organic material 41 is in contact with the buffer layer 32 and is further filled in the third hollowed-out regions 73. The barrier layer 508 located between two third hollowed-out regions 73 can be patterned to have a width slightly larger (as shown in FIG. 6) or equal to (not shown) the width of the active layer 402. In FIG. 6, the flexible organic material 41 covers all exposed surfaces of the TFT substrate and is filled in the first hollowed-out regions 71, the second hollowed-out regions 72, and the third hollowed-out regions 73. In other embodiments, if the insulating layer 50 of the TFT substrate further includes a protecting layer 506, in addition to patterning the barrier layer 508, the gate insulating layer 502 and the interlayer insulating layer 504, the protecting layer 506 can further be patterned as shown in FIG. 4 or FIG. 5.

In this embodiment, the barrier layer 508, the gate insulating layer 502, and the interlayer insulating layer 504 are all patterned for covering a necessary pattern of a lower layer, having a pattern necessary for the insulation and blocking. The first hollowed-out regions 71, the second hollowed-out regions 72, and the third hollowed-out regions 73 are disposed between adjacent TFTs. Then, the first hollowed-out regions 71, the second hollowed-out regions 72, and the third hollowed-out regions 73 are filled with the flexible organic material. Since the flexible organic material has a better buffering property than the inorganic materials of the barrier layer 508, the gate insulating layer 502, and the interlayer insulating layer 504, stress can be released to the flexible organic material in the first hollowed-out regions 71, the second hollowed-out regions 72, and the third hollowed-out regions 73 when the TFT substrate is subjected to an external transient impact. As a result, the TFT substrate has more buffer space for the stress, and the stress can be effectively absorbed and released, so that the purposes of improving the impact resistance and ameliorating the display failures are achieved. In addition, since the flexible organic material has better ductility and bending endurance than that of an inorganic layer, the flexible TFT substrate can have better bending endurance by using the flexible organic material.

In an embodiment, an overlapping area exists between a projection of the first hollowed-out region 71, a projection of the second hollowed-out region 72, and a projection of the third hollowed-out region 73 on the substrate 30, so that the hollowed-out regions in the insulating layer 50 are in communication with each other, and so that the communicated first hollowed-out region 71, second hollowed-out region 72, and third hollowed-out region 73 are continuously filled with the flexible organic material. Therefore, the stress can be released to the flexible organic material in the entire of the hollowed-out regions when the TFT substrate is subjected to an external transient impact, so that the TFT substrate has a maximum buffer space to effectively absorb and release the stress.

Furthermore, in an embodiment, the functional layer 40 can further include a capacitor (not shown). The capacitor includes a capacitor upper electrode plate (not shown) and a capacitor lower electrode plate (not shown), and the insulating layer 50 has a capacitor insulating layer (not shown) correspondingly. The capacitor upper electrode plate, the capacitor lower electrode plate, and the capacitor insulating layer are set with reference to the functional layer 40 and the insulating layer 50 in the above-described embodiments, and details are not described herein again.

The present application further provides a display panel. The display panel includes the TFT substrate in any one of the above embodiments. In this application, the inorganic layers of the TFT substrate of the display panel are each patterned for covering a necessary pattern of a lower layer, so that the inorganic layers each becomes a discontinuous film layer, and is filled with the flexible organic material, so that the surged stress in the display panel having the TFT substrate is released in these regions during the impact, thereby solving the display failure problem due to the impact.

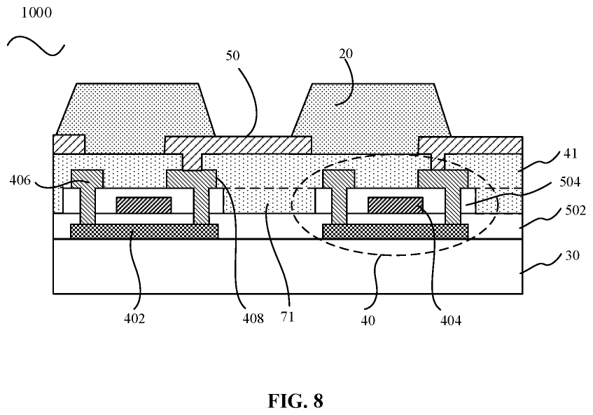

As shown in FIG. 8, a display panel 1000 in an embodiment of the present application is shown. The display panel 1000 includes the TFT substrate as shown in FIG. 1. The display panel further includes a light-emitting structure disposed on the TFT substrate. In this embodiment, the light-emitting structure is an OLED structure.

The OLED is a carrier double-injection type light-emitting device. Under driving of an external voltage, electrons and holes injected by an electrode recombine in an organic material to release energy and the energy is transferred to molecules of an organic light-emitting substance, so that the molecules of the organic light-emitting substance are excited to transition from a ground state to an excited state. When the excited molecules return from the excited state to the ground state, the excited molecules radiate and emit light.

Specifically, the OLED structure includes a first electrode, an organic light-emitting layer, and a second electrode stacked with each other. Specifically, the first electrode is directly and electrically connected to the drain electrode of the TFT, and the second electrode is opposite to the first electrode. For the OLED structure emitting light from the top, the first electrode is an anode 50 and the second electrode is a cathode (not shown). In this embodiment, the OLED structure emitting light from the top as shown in FIG. 1 is taken only as an example for describing rather than limiting the cross-sectional structure of the display panel.

In an order from the cathode to the anode, the organic light-emitting layer sequentially includes an electron injection layer, an electron transport layer, a hole blocking layer, a light-emitting layer, an electron blocking layer, a hole transport layer, and a hole injection layer (the above layers are not shown in FIG. 8). In the organic light-emitting layer, the structure corresponding to the light-emitting layer is a pixel. The organic light-emitting layer further includes a pixel defining layer 20 disposed between adjacent pixels. The pixel-defining layer 20 defines openings each corresponds to one pixel, the openings each is configured to accommodate a luminescent material and defines a region of the pixel. The luminescent materials corresponding to different colors of pixels (sub-pixels) are evaporated into corresponding openings.

In the present application, the term “pixel” can be a pixel unit or a sub-pixel constituting the pixel unit. The sub-pixel can be selected from one or more of a red sub-pixel, a blue sub-pixel, a green sub-pixel, and a white sub-pixel.

The above-described display panel includes the TFT substrate of any one of the above embodiments. The TFT substrate includes a substrate, a functional layer disposed on the substrate, and an insulating layer correspondingly covering the functional layer. The functional layer has a patterned structure, and the insulating layer has a patterned structure matching the functional layer structure. The hollowed-out region in the patterned structure of the insulating layer is filled with a flexible organic material. Since the flexible organic material has a better buffering property than the material of the insulating layer, stress can be released to the flexible organic material in the hollowed-out regions when the display panel is subjected to an external transient impact. As a result, the TFT substrate has more buffer space, and the stress can be effectively absorbed and released, so that the purposes of improving the impact resistance and ameliorating the display failures are achieved. In addition, since the flexible organic material has better ductility and bending endurance than an inorganic layer, the flexible display panel can have better bending endurance by using the flexible organic material.

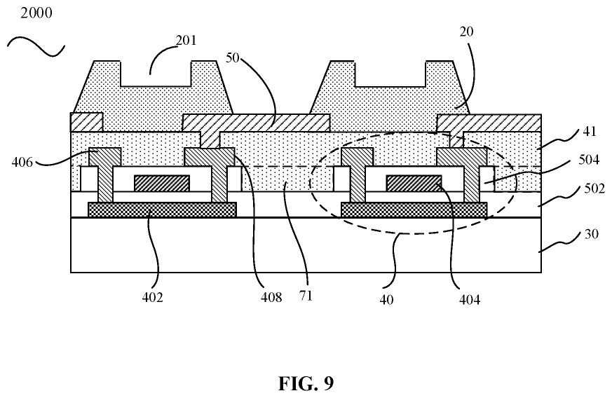

In an embodiment, the pixel defining layers of the display panel each has a channel structure defined between two adjacent pixels. As shown in FIG. 9, a display panel 2000 in an embodiment of the present application is shown. The display panel 2000 includes the TFT substrate as shown in FIG. 1. The display panel 2000 shown in FIG. 9 is different from the display panel 1000 shown in FIG. 8 in that the pixel defining layers 20 of the display panel 2000 each has a channel structure 201 defined between two adjacent pixels.

In the display panel 2000 in the above-described embodiment, by defining the channel structures 201 on the pixel defining layers 20 between each two pixels, stress can be released to the channel structures 201 when the display panel 2000 is subjected to an external transient impact, so that there is more buffer space for the stress, and the stress can be effectively absorbed and released, and the pixels are protected, thereby achieving the purposes of improving the impact resistance and ameliorating the display failures.

The technical features of the above-described exemplary embodiments can be combined arbitrarily. To simplify the description, not all possible combinations of the technical features in the above embodiments are described. However, all of the combinations of these technical features should be considered as within the scope of this application, as long as such combinations do not contradict with each other.

The above embodiments merely illustrate several embodiments of this application, and the description thereof is specific and detailed, but shall not be constructed as limiting the scope of the application. It should be noted that, for a person of ordinary skill in the art, several variations and improvements can be made without departing from the concept of this application, and these are all within the protection scope of this application. Therefore, the protection scope of this application shall be decided by the appended claims.

1. A TFT substrate, comprising:
a substrate;
a functional layer comprising an active layer and a gate electrode sequentially disposed on the substrate; and
an insulating layer comprising a gate insulating layer and an interlayer insulating layer, the gate insulating later being disposed on the substrate and overlaying the active layer, and the interlayer insulating layer being disposed on the gate insulating layer and overlaying the gate electrode, wherein the interlayer insulating layer defines a first hollowed-out region at a position corresponding to two ends of the active layer, and the first hollowed-out region is filled with a flexible organic material.

2. The TFT substrate of claim 1, wherein a width of the interlayer insulating layer located between two first hollowed-out regions is greater than or equal to a width of the active layer.

3. The TFT substrate of claim 1, wherein the flexible organic material comprises a first flexible organic layer and a second flexible organic layer located above the first flexible organic layer, and a material of the second flexible organic layer is different from a material of the first flexible organic layer.

4. The TFT substrate of claim 3, wherein the first flexible organic layer is a non-Newtonian fluid.

5. The TFT substrate of claim 3, wherein the second flexible organic layer is a planarization layer.

6. The TFT substrate of claim 1, wherein the gate insulating layer defines a second hollowed-out region at a position corresponding to the two ends of the active layer, and the flexible organic material is filled in the second hollowed-out region.

7. The TFT substrate of claim 6, wherein the functional layer further comprises a source electrode and a drain electrode, and the insulating layer further comprises a protecting layer overlaying the source electrode and the drain electrode.

8. The TFT substrate of claim 7, wherein the protecting layer further covers the interlayer insulating layer located between the source electrode and the drain electrode.

9. The TFT substrate of claim 7, further comprising a buffer layer overlaying the substrate, wherein the flexible organic material is in contact with the buffer layer, the insulating layer further comprises a barrier layer disposed between the buffer layer and the active layer, the barrier layer defines a third hollowed-out region at a position corresponding to the two ends of the active layer, and the flexible organic material is in contact with the buffer layer and further filled in the third hollowed-out region.

10. The TFT substrate of claim 9, wherein a width of the barrier layer is greater than or equal to a width of the active layer.

11. The TFT substrate of claim 9, wherein the first hollowed-out region, the second hollowed-out region, and the third hollowed-out region are in communication with each other, so that the first hollowed-out region, the second hollowed-out region, and the third hollowed-out region are continuously filled with the flexible organic material.

12. The TFT substrate of claim 1, wherein the flexible organic material comprises at least one of polyacrylate and polyimide.

13. The TFT substrate of claim 1, wherein a material of the insulating layer comprises at least one of silicon oxide and silicon nitride.

14. The TFT substrate of claim 1, wherein the TFT substrate comprises a plurality of alternately stacked functional layers and insulating layers, the plurality of alternately stacked functional layers and insulating layers is characterized by a patterned structure, and an overlapping area exists between a projection of the patterned structure of each of the functional layers on the substrate and a projection of the patterned structure of each of the insulating layers on the substrate.

15. A display panel comprising the TFT substrate of claim 1.

16. The display panel of claim 15, further comprising:
a light-emitting structure disposed on the TFT substrate, the light-emitting structure comprising a first electrode, an organic light-emitting layer, and a second electrode stacked with each other;
the organic light-emitting layer comprising pixels and a pixel defining layer disposed between adjacent pixels;
the pixel defining layer defines a channel structure between two adjacent pixels.

17. The display panel of claim 16, wherein the light-emitting structure is an OLED structure.
